(19) United States
(12) Patent Application Publication
(10) Pub. No.: US 2025/0327762 A1
(43) Pub. Date: Oct. 23, 2025

(54) COMPOSITE SEMICONDUCTOR INSPECTION SYSTEM

(71) Applicant: NanoSeex Inc., Hsinchu County (TW)

(72) Inventors: YU-YAN AU YONG, Hsinchu County (TW); CHIA-YU LIN, Hsinchu County (TW); TSUNG-HSIEN HAN, Hsinchu County (TW); CHUN-TING LIU, Hsinchu County (TW); PO-CHING HE, Hsinchu County (TW); PO-TSANG WU, Hsinchu County (TW)

(21) Appl. No.: 18/991,662

(22) Filed: Dec. 22, 2024

(30) Foreign Application Priority Data
Apr. 23, 2024 (TW) 113115006

(51) Int. Cl. G01N 23/18; G01N 21/88; G01N 21/95

(52) U.S. Cl. CPC G01N 23/18; G01N 21/8806; G01N 21/9501; G01N 2223/6116

(57) ABSTRACT

A composite semiconductor inspection system is provided, which includes a multi-axis sample stage, an optical measurement subsystem, an X-ray measurement subsystem and a processing device. The optical measurement subsystem includes a light source generator, an incident-end optical element group, a receiving-end optical element group and an optical receiver. The optical receiver is used to receive an optical signal to-be-measured and generate corresponding optical spectrum information. The X-ray measurement subsystem includes an X-ray generator, an X-ray optical element group and an X-ray detector. The X-ray detector is used to receive an X-ray signal to-be-measured and generate corresponding X-ray spectrum information. The processing device is configured to execute a fitting analysis program based on the optical spectrum information and the X-ray spectrum information to obtain structural parameters of a sample to-be-tested as analysis results.

### CROSS-REFERENCE TO RELATED PATENT APPLICATION

This application claims the benefit of priority to Taiwan Patent Application No. 113115006, filed on Apr. 23, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a system, and more particularly to a composite semiconductor inspection system characterized by high efficiency and high precision, suitable for various complex semiconductor products.

### BACKGROUND OF THE DISCLOSURE

The semiconductor industry is rapidly evolving through continuous innovation, driving the development of new structures tailored to meet the needs of various terminal applications. In the field of integrated circuit manufacturing, three-dimensional nanoscale structures, such as Gate-All-Around (GAA) and Complementary FET (CFET) structures, have been developed to enhance drive current, reduce voltage, and improve transistor efficiency. Similarly, in memory manufacturing, vertical stacking with high aspect ratio structures, such as 3D NAND, has been introduced to increase memory density per unit area, enhance storage performance, and accelerate data read/write speeds. To address the challenges presented by these advanced processes and structures, the development of advanced measurement equipment has become a critical focus for improving manufacturing yield.

Historically, optical measurement technology has played a dominant role in integrated circuit production lines. However, with the increased use of metal oxide materials and the rise in layer counts for high aspect ratio memory structures—now exceeding 200 layers—the limitations of optical technology have become apparent. In response, X-ray technology has been adopted to offer superior penetration and improved measurement resolution. Despite these advancements, there remains a lack of a single system or equipment capable of supporting a wide range of measurement tasks across diverse process technologies.

### SUMMARY OF THE DISCLOSURE

In response to the above-referenced technical inadequacies, the present disclosure addresses the technical problem of providing a composite semiconductor inspection system that overcomes the deficiencies of the prior art. This system is characterized by high efficiency and high precision and is suitable for various complex semiconductor products.

To solve the above technical problem, one technical solution provided by the present disclosure is a composite semiconductor inspection system, comprising a multi-axis sample stage, an optical measurement subsystem, an X-ray measurement subsystem, and a processing device. The multi-axis sample stage is configured to carry a sample to-be-tested. The optical measurement subsystem includes a light source generator, an incident-end optical element group, a receiving-end optical element group, and an optical receiver. The light source generator is configured to generate a measurement light beam with a wavelength in the optical wavelength range, which at least covers at least an ultraviolet light band to a near-infrared light band. The incident-end optical element group guides the measurement light beam to the sample to-be-tested. The receiving-end optical element group receives an optical signal to-be-measured generated by the measurement light beam irradiating the sample to-be-tested. The optical receiver receives the to-be-measured optical signal guided by the receiving-end optical element group and generates optical spectrum information corresponding to the to-be-measured optical signal. The X-ray measurement subsystem includes an X-ray generator, an X-ray optical element group, and an X-ray detector. The X-ray generator generates a measurement X-ray beam. The X-ray optical element group guides the measurement X-ray beam to the sample to-be-tested. The X-ray detector receives an X-ray signal to-be-measured generated when the measurement X-ray beam irradiates the sample to-be-tested and generates X-ray spectrum information corresponding to the X-ray signal to-be-measured. The processing device is configured to execute a fitting analysis program based on the optical spectrum information and the X-ray spectrum information to obtain one or more structural parameters of the sample to-be-tested as analysis results.

To solve the above technical problem, another technical solution provided by the present disclosure is a composite semiconductor inspection system comprising a multi-axis sample stage, at least two optical measurement subsystems, and a processing device. The multi-axis sample stage is configured to carry a sample to-be-tested. Each of the at least two optical measurement subsystems includes a light source generator, an incident-end optical element group, a receiving-end optical element group, and an optical receiver. The light source generator generates a measurement light beam with a wavelength in the optical wavelength range, covering at least an ultraviolet light band to a near-infrared light band. The incident-end optical element group guides the measurement light beam to the sample to-be-tested. The receiving-end optical element group receives an optical signal to-be-measured generated by the measurement light beam irradiating the sample to-be-tested. The optical receiver receives the to-be-measured optical signal guided by the receiving-end optical element group and generates optical spectrum information corresponding to the to-be-measured optical signal. The processing device is configured to execute a fitting analysis program based on the optical spectrum information generated by the at least two optical measurement subsystems to obtain one or more structural parameters of the sample to-be-tested as analysis results.

To solve the above technical problem, yet another technical solution provided by the present disclosure is a composite semiconductor inspection system comprising a multi-axis sample stage, at least two X-ray measurement subsystems, and a processing device. The multi-axis sample stage is configured to carry a sample to-be-tested. Each of the at least two X-ray measurement subsystems includes an X-ray generator, an X-ray optical element group, and an X-ray detector. The X-ray generator generates a measurement X-ray beam. The X-ray optical element group guides the measurement X-ray beam to the sample to-be-tested. The X-ray detector receives an X-ray signal to-be-measured generated when the measurement X-ray beam irradiates the sample to-be-tested and generates X-ray spectrum information corresponding to the X-ray signal to-be-measured. The processing device is configured to execute a fitting analysis program based on the X-ray spectrum information generated by the at least two X-ray measurement subsystems to obtain one or more structural parameters of the sample to-be-tested as analysis results.

One advantageous effect of the present disclosure is that the composite semiconductor inspection system integrates X-ray measurement and optical measurement technologies and incorporates machine learning based on neural networks for result analysis. The system can feed information obtained through X-ray measurement back into the optical measurement model, enabling more precise analysis results. Furthermore, the system combines the penetrative capability of X-ray measurement technology with the speed of optical measurement technology, providing a comprehensive and highly efficient measurement solution capable of analyzing various complex semiconductor components.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a functional block diagram of the composite semiconductor inspection system according to the first embodiment of the present disclosure.

FIG. 2 is a schematic diagram of the system architecture of the composite semiconductor inspection system according to the first embodiment of the present disclosure.

FIG. 3 is a top view of the measurement architecture of the composite semiconductor inspection system according to the first embodiment of the present disclosure.

FIG. 4 is a schematic diagram of the neural network used in the fitting analysis program according to the embodiment of the present disclosure.

FIG. 5 is a functional block diagram of the composite semiconductor inspection system according to the second embodiment of the present disclosure.

FIG. 6 is a schematic diagram of the system architecture of the composite semiconductor inspection system according to the second embodiment of the present disclosure.

FIG. 7 is a top view of the measurement architecture of the composite semiconductor inspection system according to the second embodiment of the present disclosure.

FIG. 8 is a functional block diagram of the composite semiconductor inspection system according to the third embodiment of the present disclosure.

FIG. 9 is a schematic diagram of the system architecture of the composite semiconductor inspection system according to the third embodiment of the present disclosure.

FIG. 10 is a top view of the measurement architecture of the composite semiconductor inspection system according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

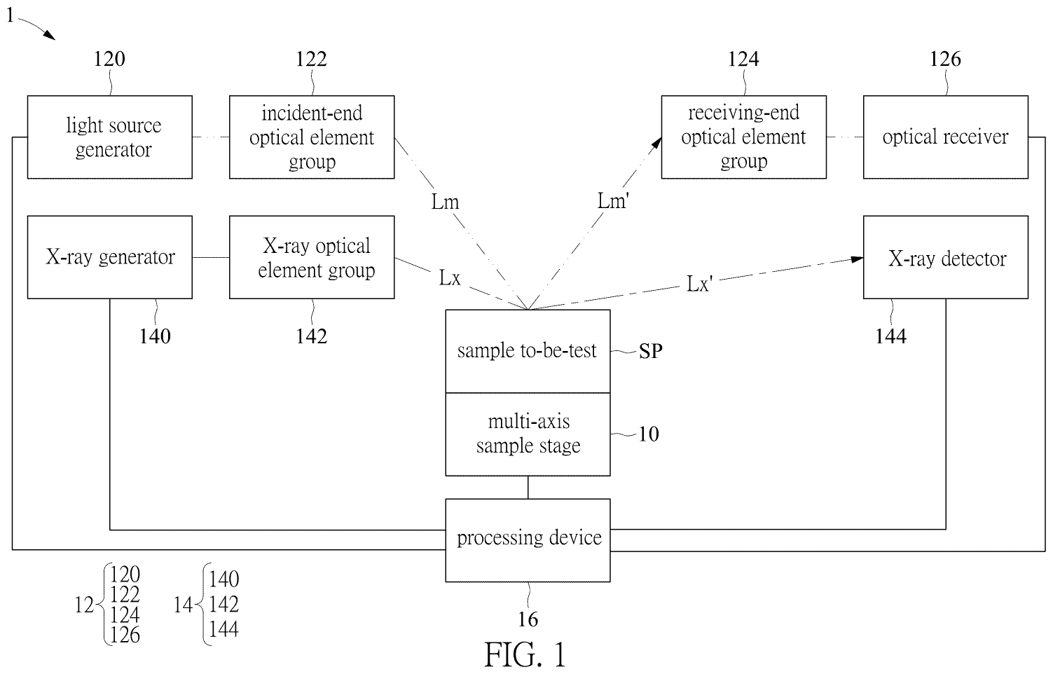

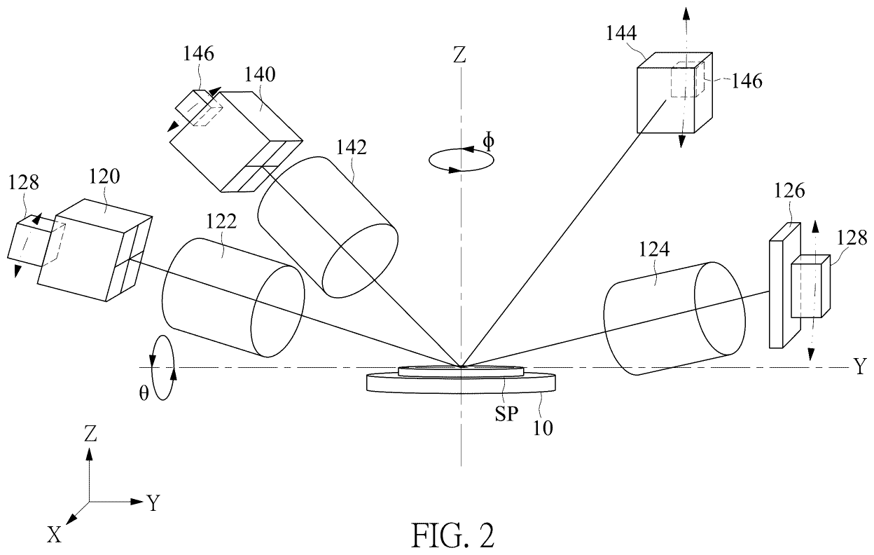

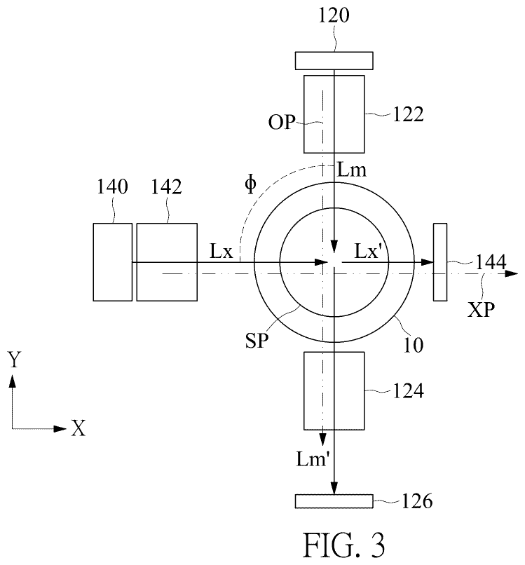

FIG. 1 is a functional block diagram of the composite semiconductor inspection system according to the first embodiment of the present disclosure, FIG. 2 is a schematic diagram of the system architecture of the composite semiconductor inspection system according to the first embodiment of the present disclosure and FIG. 3 is a top view of the measurement architecture of the composite semiconductor inspection system according to the first embodiment of the present disclosure.

Referring to FIGS. 1 to 3, the first embodiment provides a composite semiconductor inspection system 1, including a multi-axis sample stage 10, an optical measurement subsystem 12, an X-ray measurement subsystem 14, and a processing device 16.

The multi-axis sample stage 10 is a movable stage capable of multi-axis movement. For example, the multi-axis sample stage 10 can be a three-axis tilt platform or a gimbal tilt platform, and is used to hold a sample to-be-tested SP. The multi-axis sample stage 10 may include a stage translation mechanism and a stage rotation mechanism. The stage translation mechanism can, for instance, include stepper motors corresponding to three axes, enabling the sample to-be-tested SP to move along one or more of the X-axis, Y-axis, and Z-axis. By controlling the stepper motor on each axis, the sample to-be-tested SP can be precisely moved to different positions. Taking the gimbal tilt platform as an example, the stage rotation mechanism can include a gimbal joint connected to the platform, allowing the sample to-be-tested SP to rotate about one or more of the X-axis, Y-axis, and Z-axis. Specifically, the rotation mechanism of the multi-axis sample stage 10 may include controlling the azimuth angle θ around the Y-axis and the azimuth angle Φ around the Z-axis, thereby enabling comprehensive scanning of the sample to-be-tested SP.

In the embodiments of the present disclosure, the sample to-be-tested SP may include wafers, photomasks, photomask films, or semiconductor devices with multilayer structures.

The optical measurement subsystem 12 includes a light source generator 120, an incident-end optical element group 122, a receiving-end optical element group 124, and an optical receiver 126. The light source generator 120 is used to generate a measurement light beam (Lm) with a wavelength within an optical wavelength range, which at least covers the ultraviolet light band to the near-infrared light band. More specifically, the light source generator 120 can produce measurement light beams Lm with wavelengths ranging from 200 nm to 3000 nm. In some embodiments, the light source generator 120 may include components such as Ti-sapphire lasers, mercury arc lamps, or halogen lamps, thereby allowing it to produce measurement light beams Lm with various wavelengths.

The incident-end optical element group 122 is used to guide the measurement light beam to the sample to-be-tested. The incident-end optical element group 122 may include one or more optical elements. In this embodiment, the incident-end optical element group 122 can include, for example, an optical filter, an optical collimator, an optical polarizer, and an optical compensator arranged sequentially between the light source generator 120 and the sample to-be-tested SP. However, the present disclosure is not limited to this configuration, and suitable optical elements for the incident-end optical element group 122 can be selected based on user requirements. The optical filter can filter out stray light from the light source generator 120, so as to remove wavelengths outside the target detection range. The optical collimator can collimate divergent light from the light source generator 120 into a symmetrical and well-aligned measurement light beam Lm. The optical polarizer can filter the measurement light beam Lm to allow light in a specific direction to pass, so as to impart polarization characteristics to the beam. The optical compensator can convert the polarized light from the optical polarizer into circularly or elliptically polarized light.

Similarly, the receiving-end optical element group 124 may also include one or more optical elements, which are used to receive the optical signal (Lm′) generated when the measurement light beam Lm illuminates the sample to-be-tested SP. The receiving-end optical element group 124 may sequentially include optical filters, optical collimators, optical polarizers, and optical compensators. The purposes of the optical filter and optical collimator are as described above. The optical polarizer in the receiving-end group may be a rotating polarizer, which can convert the measurement light beam Lm into a polarized light source after passing through the optical compensator in the incident-end group 122. Similarly, the optical compensator in the receiving-end group 124 may be a rotating compensator, where rotation improves measurement accuracy.

The optical receiver 126 is used to receive the optical signal to-be-measured Lm′ guided by the receiving-end optical element group 124 and generate optical spectrum information corresponding to the optical signal to-be-measured Lm′. The optical receiver 126 may, for example, be a spectrometer that receives the optical signal to-be-measured Lm′ reflected or scattered from the sample to-be-tested SP.

During the measurement process, the processing device 16 may control the multi-axis sample stage 10 to move and/or rotate so that the optical receiver 126 of the optical measurement subsystem 12 can receive the plurality of optical signals to-be-measured Lm′ generated at various optical measurement positions and/or optical measurement angles. It then produces a plurality of pieces of optical spectrum information corresponding to these optical signals to-be-measured Lm′.

Additionally, the light source generator 120 and the optical receiver 126 are installed on an optical rotation mechanism 128. The optical rotation mechanism 128 may include one or more robotic arms connected to the light source generator 120 and the optical receiver 126. Each robotic arm may have the plurality of degrees of freedom, allowing the light source generator 120 and the optical receiver 126 to rotate around the sample to-be-tested SP either simultaneously or independently. In this setup, when the processing device 16 controls the multi-axis sample stage 10 to move and/or rotate, it can also control the optical rotation mechanism 128 to rotate, enabling the light source generator 120 to direct the measurement light beam Lm from the plurality of directions and allowing the optical receiver 126 to receive the plurality of optical signals to-be-measured Lm′ from different optical measurement angles, so as to produce the plurality of corresponding pieces of optical spectrum information.

On the other hand, the X-ray measurement subsystem 14 includes an X-ray generator 140, an X-ray optical element group 142, and an X-ray detector 144. The X-ray generator 140 may include an X-ray tube containing an electron beam emitter and a target material. When the target material is bombarded by accelerated electron beams, it generates an X-ray beam Lx. Additionally, by selecting different target materials, such as copper (Cu), iron (Fe), or molybdenum (Mo), X-ray beams Lx of varying energy levels or wavelengths (or frequencies) can be produced.

The X-ray optical element group 142 is used to guide the X-ray beam Lx to the sample to-be-tested. The X-ray optical element group 142 may include one or more X-ray optical elements. For example, it may include a multilayer mirror, an X-ray slit, and an X-ray collimator arranged sequentially between the X-ray generator 140 and the sample to-be-tested SP. The multilayer mirror can focus the X-ray beam Lx both horizontally and vertically. The X-ray slit can control the flux of the beam incident on the sample to-be-tested SP and its vertical divergence angle. The X-ray beam Lx, primarily used in X-ray analysis, may have a wavelength greater than 0.1 nanometers and may include hard X-rays, soft X-rays, or gamma rays.

When the measurement X-ray beam Lx irradiates the sample to-be-tested SP, depending on the angle of incidence, the X-ray signal to-be-measured Lx′ may be generated due to reflection, diffraction, scattering, or transmission. By positioning the X-ray detector 144 appropriately, the X-ray signal to-be-measured Lx′ resulting from reflection, diffraction, scattering, or transmission, can be received, and corresponding X-ray spectrum information can be generated. The X-ray detector 144 may be a high-spatial-resolution detector with one or more dimensions and is capable of collecting the X-ray signal to-be-measured Lx′ with energies exceeding 1 keV.

During the measurement process, the processing device 16 may control the multi-axis sample stage 10 to move and/or rotate so that the X-ray detector 144 receives the plurality of X-ray signals to-be-measured Lx′ generated at various optical measurement positions and/or X-ray measurement angles, thereby producing the plurality of pieces of X-ray spectrum information corresponding to the X-ray signal to-be-measured Lx′.

Additionally, the X-ray generator 140 and the X-ray detector 144 are mounted on the X-ray rotation mechanism 146. The X-ray rotation mechanism 146 may include one or more robotic arms connected to the X-ray generator 140 and the X-ray detector 144. Each robotic arm may have the plurality of degrees of freedom, enabling the X-ray generator 140 and the X-ray detector 144 to rotate around the sample to-be-tested SP either simultaneously or independently. Within this framework, while the processing device 16 controls the multi-axis sample stage 10 to move and/or rotate, it can also control the X-ray rotation mechanism 146 to rotate, thereby allowing the X-ray generator 140 to direct the measurement X-ray beam Lx from the plurality of directions and enabling the X-ray detector 144 to receive the plurality of X-ray signals to-be-measured Lx′ generated at various X-ray measurement angles, thereby producing the plurality of pieces of X-ray spectrum information corresponding to the plurality of X-ray signals to-be-measured Lx′.

Referring to FIG. 3, the X-axis and Y-axis can form a reference plane. The optical measurement subsystem 12 projects an optical measurement path OP onto this reference plane, and the X-ray measurement subsystem projects an X-ray measurement path XP onto the same plane. The optical measurement path OP and the X-ray measurement path XP are perpendicular to each other. This arrangement allows the composite semiconductor inspection system 1 provided by the present disclosure to meet the requirements of both anisotropic and isotropic measurements. For example, during measurements with the X-ray measurement subsystem 14, the optical measurement subsystem 12 can simultaneously perform measurements at a specified azimuth angle ϕ, so as to achieve anisotropic measurements in real-time. To achieve the requirement for collinear measurement, after the X-ray measurement subsystem 14 completes the measurement, the multi-axis sample stage 10 can be rotated along the Z-axis to the corresponding azimuth angle Φ, causing the sample to-be-tested SP to rotate. This allows the X-ray measurement subsystem 14 and the optical measurement subsystem 12 to perform measurements at the same position and spatial characteristics. Consequently, accurate measurements of both the X-ray signal to-be-measured Lx′ and the optical signal to-be-measured Lm′ can be obtained from the same orientation and position within the same system.

The processing device 16 may, for example, be a computer system comprising a processor and memory, configured to execute stored instruction sets or codes to control the controllable components within the multi-axis sample stage 10, the optical measurement subsystem 12, and the X-ray measurement subsystem 14. Furthermore, the processing device 16 may be configured to execute a fitting analysis program based on the optical spectrum information and X-ray spectrum information to determine one or more structural parameters of the sample to-be-tested as analysis results. The structural parameters may include one or more of thickness, roughness, density, critical dimension (CD), line edge roughness (LER), refractive index, and extinction coefficient.

For example, the processing device 16 may execute a plurality of electromagnetic wave computation engines based on different physical mechanisms to fit the optical spectrum information and X-ray spectrum information. The optical spectrum information may include reflection spectrum obtained by directing the measurement light beam Lm onto the sample to-be-tested SP at various angles of incidence, while the X-ray spectrum information may include reflection spectrum obtained by directing the measurement X-ray beam Lx onto the sample to-be-tested SP at various angles of incidence. The fitting results may include structural parameters of the sample to-be-tested SP, such as the critical dimensions of GAA-FETs. These electromagnetic wave computation engines may include one or more of the Finite-Difference Time-Domain (FDTD) algorithm, Distorted Wave Born Approximation (DWBA) algorithm, Rigorous Coupled Wave Analysis (RCWA) algorithm, Discrete Dipole Approximation (DDP) algorithm, and Boundary Element Method (BEM).

Specifically, the processing device 16 may use electromagnetic models established by these electromagnetic wave computation engines for the optical system to simulate and fit the optical spectrum information and X-ray spectrum information, thereby reconstructing the critical structural parameters of the sample to-be-tested SP in a reverse engineering manner.

In this embodiment, the optical spectrum information may be generated by various interaction mechanisms between the measurement light beam Lm and the sample to-be-tested SP. For instance, the optical spectrum information may include optical reflection spectrum information and optical scattering spectrum information. The optical reflection spectrum information can be obtained by appropriately controlling the azimuth angles θ and Φ, allowing the light source generator 120 to direct the measurement light beam Lm with the plurality of wavelengths and at the plurality of incidence angles, while the optical receiver 126 collects the optical signal to-be-measured Lm′ generated by reflection. Similarly, the optical scattering spectrum information may be obtained by the optical receiver 126 collecting the optical signal to-be-measured Lm′generated by scattering. Consequently, in the fitting analysis program, the processing device 16 can apply the same or different electromagnetic wave computation engines to fit the optical reflection and scattering spectrum information, thereby reverse-reconstructing the critical structural parameters of the sample to-be-tested SP.

Similarly, the X-ray spectrum information can be generated through different interaction mechanisms between the measurement X-ray beam Lx and the sample to-be-tested SP. For example, the X-ray spectrum information can include X-ray reflection spectrum information, X-ray scattering spectrum information, X-ray diffraction spectrum information and X-ray fluorescence spectrum information. The optical reflection map information can enable the X-ray detector 144 to collect the X-ray signal to-be-measured Lx′ generated due to reflection by appropriately controlling the azimuth angles θ and Φ. Similarly, the X-ray scattering map information, X-ray diffraction map information and the X-ray fluorescence spectrum information can be obtained by the X-ray detector 144 collecting the X-ray signal to-be-measured Lx′ generated due to scattering, diffraction and fluorescence excitation respectively. Therefore, in the fitting analysis process, the processing device 16 can perform fitting analyses on X-ray reflection spectrum information, X-ray scattering spectrum information, X-ray diffraction spectrum information and X-ray fluorescence spectrum information using identical or distinct electromagnetic wave computation engines. These analyses include X-ray reflectivity (XRR) analysis, X-ray diffraction (XRD) analysis, small-angle X-ray scattering (SAX) analysis, and X-ray fluorescence (XRF) analysis. The results of these analyses enable the reverse reconstruction of critical structural parameters of the sample to-be-tested SP.

Taking XRR analysis as an example, when the measurement X-ray beam Lx is incident on the surface of the sample to-be-tested SP, XRR analysis can determine the structural parameters of the sample to-be-tested SP. For instance, when the sample to-be-tested SP includes a multilayer structure, XRR analysis can determine the density, thickness, and roughness of each layer based on the collected X-ray reflectivity spectrum. On the other hand, when the sample to-be-tested SP contains microcomponents (e.g., gate-all-around field-effect transistors (GAA-FET)), XRR analysis can determine the orientation and critical dimensions of the GAA-FET based on the X-ray reflectivity spectrum.

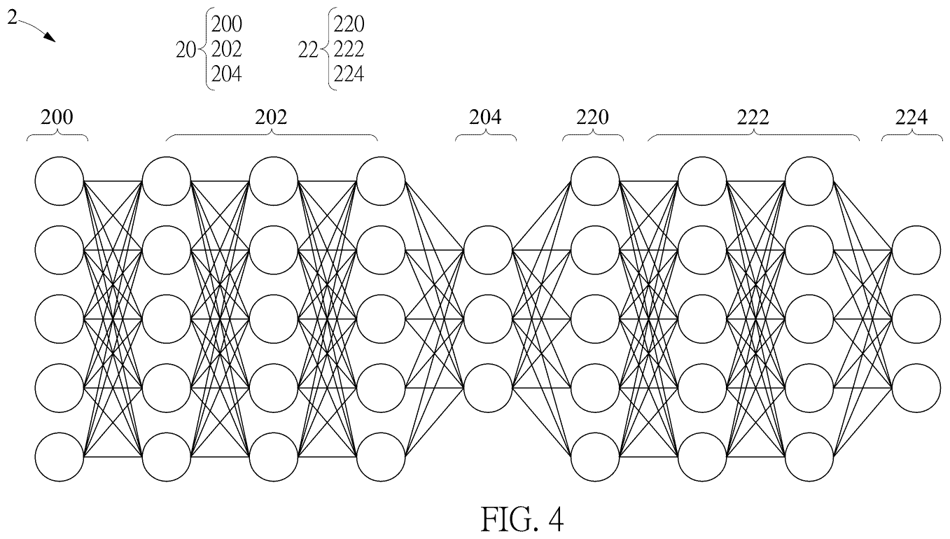

Please refer to FIG. 4, which illustrates a schematic diagram of the neural network model used in the fitting analysis program in an embodiment of the present disclosure. Notably, when the processing device 16 executes the fitting analysis program, it may include inputting the generated optical spectrum information into the neural network model 2 shown in FIG. 4. The neural network model 2 includes a pre-trained machine learning structure 20 and a measurement data analysis structure 22.

The pre-trained machine learning structure 20 may comprise an input layer 200, a plurality of hidden layers 202, and an output layer 204. The pre-trained machine learning structure 20 is trained to generate a plurality of optical prediction results and a plurality of X-ray prediction results based on the target sample to-be-tested architecture and a plurality of preset structural parameters corresponding to the target sample to-be-tested architecture.

It should be noted that the target sample to-be-tested architecture may represent a known component structure in the sample to-be-tested SP, such as vertically stacked and interconnected 3D NAND memory, Gate-All-Around (GAA) structures, and Complementary MOSFET (CMOS) structures. The preset structural parameters may be theoretical structural parameters used during the manufacturing of these components, including multi-layer/single-layer film thickness, roughness, density, critical dimension (CD) of nanostructures, line edge roughness (LER), and n, k values of special semiconductor materials.

The input layer 200 serves to input these structural parameters into the hidden layers 202. Each hidden layer 202 may be assigned specific weights or thresholds based on theoretical requirements or user-defined criteria to facilitate data analysis. After processing the plurality of data entries or simulation results, the information is transmitted to the output layer 204. The output layer 204 produces optical prediction results and X-ray prediction results based on the computations and processing performed by the hidden layers 202. These results may correspond to the predicted optical spectrum information and X-ray spectrum information, respectively.

Subsequently, the processing device 16 further inputs the optical prediction results, X-ray prediction results, optical spectrum information, and X-ray spectrum information into the measurement data analysis structure 22. Similarly, the measurement data analysis structure 22 may include an input layer 220, a plurality of hidden layers 222, and an output layer 224. The measurement data analysis structure 22 is trained to perform modeling and analysis based on the optical spectrum information and X-ray spectrum information using the target sample to-be-tested architecture, thereby obtaining the structural parameters of the sample to-be-tested SP through reverse inference. Additionally, the measurement data analysis structure 22 further restricts the fitting range used for the sample to-be-tested SP based on the optical and X-ray prediction results generated by the pre-trained machine learning structure 20. This approach enables faster and more precise computational analysis of the structural parameters of the sample to-be-tested SP.

Thus, in the composite semiconductor inspection system provided by the first embodiment of the present disclosure, the integration of X-ray measurement and optical measurement technologies, combined with neural network-based machine learning for result analysis, enables feedback of X-ray measurement data into the optical measurement model. This results in more accurate analysis outcomes. Furthermore, this composite semiconductor inspection system merges the penetrating capability of X-ray measurement technology with the speed of optical measurement technology, so as to provide a comprehensive and highly efficient measurement solution capable of analyzing various complex semiconductor components.

### Second Embodiment

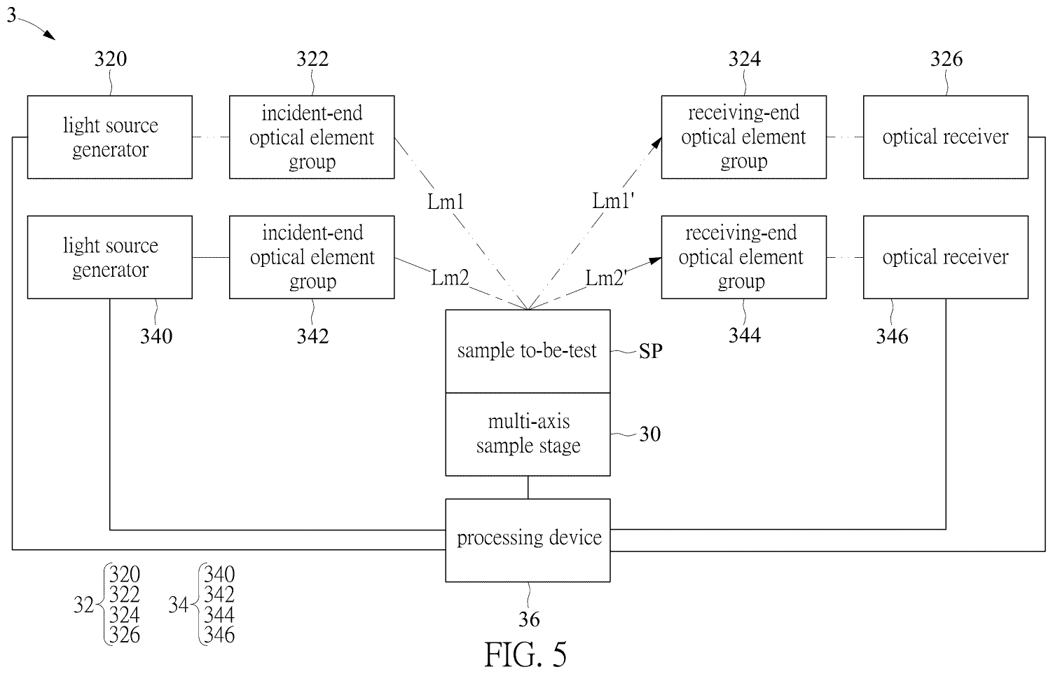

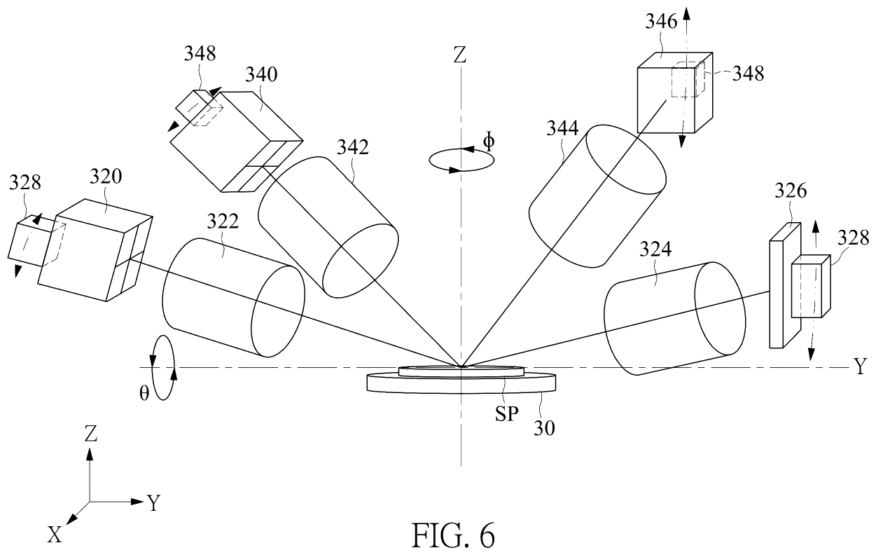

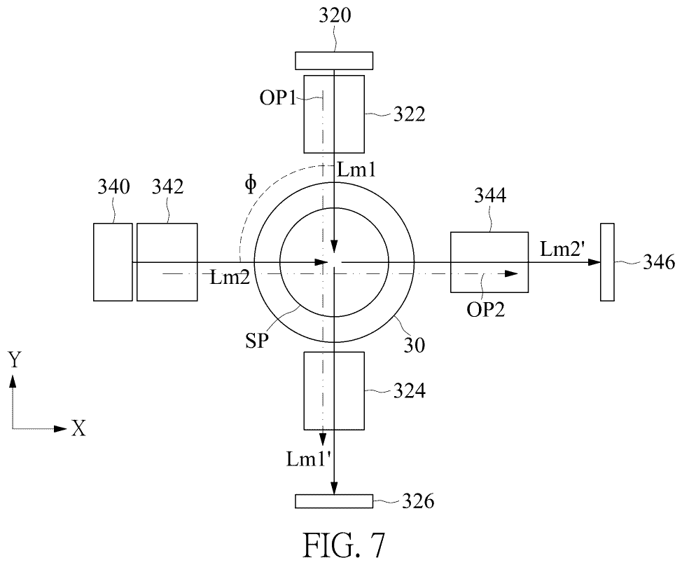

FIG. 5 shows a functional block diagram of the composite semiconductor inspection system in the second embodiment of the present disclosure. FIG. 6 depicts the system architecture diagram, and FIG. 7 illustrates top view of the measurement architecture. This second embodiment provides an alternative composite semiconductor inspection system 3, comprising a multi-axis sample stage 30, optical measurement subsystems 32 and 34, and a processing device 36. In this embodiment, elements that are identical or similar to those in the first embodiment are denoted by similar reference numerals, and their descriptions are omitted to avoid redundancy.

The multi-axis sample stage 30 is similar to the multi-axis sample stage 10 in the first embodiment. The optical measurement subsystems 32 and 34 are fundamentally similar to the optical measurement subsystem 12. The optical measurement subsystem 32 includes a light source generator 320, an incident-end optical element group 322, a receiving-end optical element group 324, and an optical receiver 326. The optical measurement subsystem 34 includes a light source generator 340, an incident-end optical element group 342, a receiving-end optical element group 344, and an optical receiver 346. The light source generators 320 and 340 are configured to produce measurement light beams Lm1 and Lm2, respectively, with wavelengths within an optical wavelength range, which at least covers the ultraviolet light band to the near-infrared light band. The incident-end optical element groups 322 and 342 are used to direct the measurement light beams Lm1 and Lm2 to the sample to-be-tested SP. The receiving-end optical element groups 324 and 344 are used to receive the optical signals to-be-measured Lm1′ and Lm2′ generated when the measurement light beams Lm1 and Lm2 irradiate the sample to-be-tested SP. The optical receivers 326 and 346 are used to receive the optical signals to-be-measured Lm1′ and Lm2′ guided by the receiving-end optical element groups 324 and 344, respectively, and to generate the optical spectrum information corresponding to the optical signals to-be-measured Lm1′ and Lm2′.

It should be noted that the primary difference between the second embodiment and the first embodiment lies in the replacement of the X-ray measurement subsystem 14 with the optical measurement subsystem 34 in the second embodiment. As shown in FIG. 7, the X-axis and Y-axis form a reference plane. The optical measurement subsystem 32 projects an optical measurement path OP1 onto this reference plane, while the optical measurement subsystem 34 projects an optical measurement path OP2 onto the same plane. These paths OP1 and OP2 are perpendicular to each other. Consequently, the composite semiconductor inspection system 3 provided by the present disclosure achieves anisotropic measurement capabilities. For instance, while the optical measurement subsystem 32 is performing measurements, the optical measurement subsystem 34 can simultaneously measure at a specified azimuth angle ϕ, thereby achieving anisotropic measurements in real-time. This setup significantly enhances data throughput and reduces the time required to generate optical spectrum information. It is conceivable that consistent measurement conditions for both optical measurement subsystems 32 and 34 could also achieve isotropic measurement capabilities.

On the other hand, the light source generator 320 and the optical receiver 326 are mounted on the optical rotation mechanism 328, while the light source generator 340 and the optical receiver 346 are mounted on the optical rotation mechanism 348. The optical rotation mechanisms 328 and 348 may each include one or more robotic arms, with each robotic arm having the plurality of degrees of freedom. This configuration allows the light source generators 320 and 340, as well as the optical receivers 326 and 346, to rotate simultaneously or independently around the sample to-be-tested SP.

Additionally, although two sets of optical measurement subsystems 32 and 34 are employed in this embodiment, the present disclosure is not limited to this configuration. The number of optical measurement subsystems can be designed according to user requirements. Furthermore, the number of light source generators, incident-end optical element groups, receiving-end optical element groups, and optical receivers is not restricted to the quantities illustrated in FIGS. 5 through 7. For example, only one set of light source generators and incident-end optical element groups may be provided, while the plurality of sets of receiving-end optical element groups and optical receivers can be configured.

Moreover, similar to the first embodiment, the processing device 36 may execute a fitting analysis program based on the optical spectrum information generated by the optical measurement subsystems 32 and 34 to obtain the structural parameters of the sample to-be-tested SP as the analysis result. When the processing device 36 executes the fitting analysis program, it may include inputting the generated optical spectrum information into the neural network model 2, as shown in FIG. 4. Since the details of data processing by the neural network model 2 are similar to those described in the first embodiment, they are omitted here for brevity.

### Third Embodiment

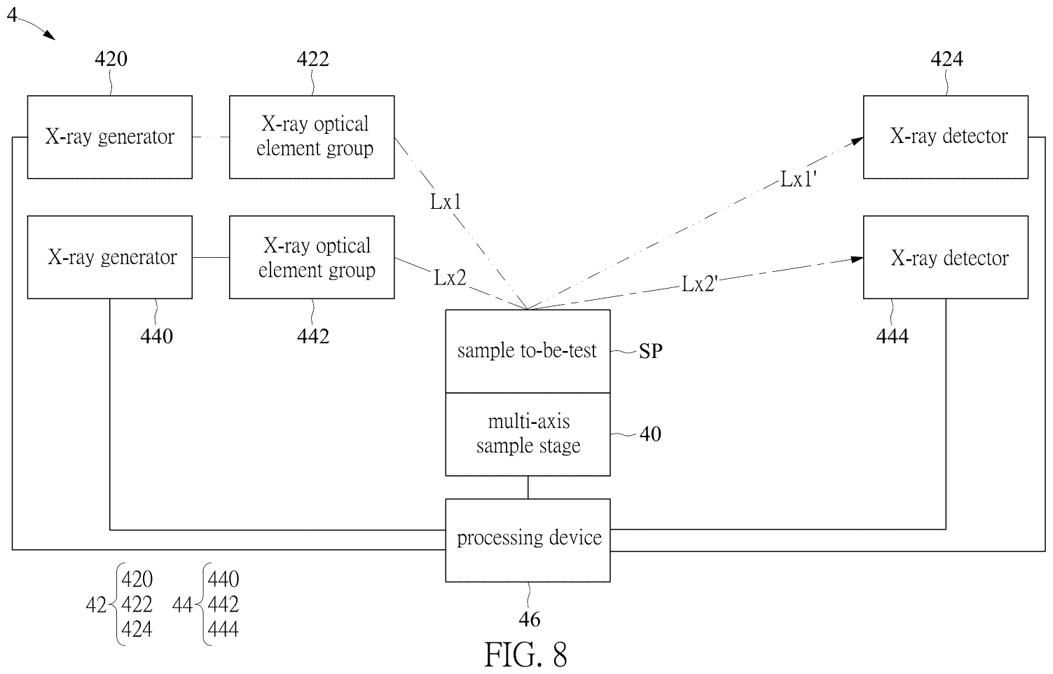

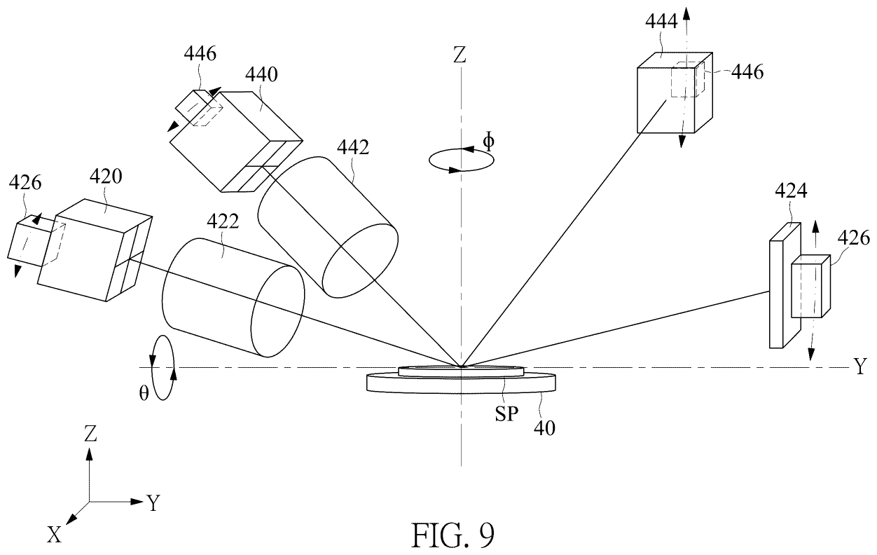

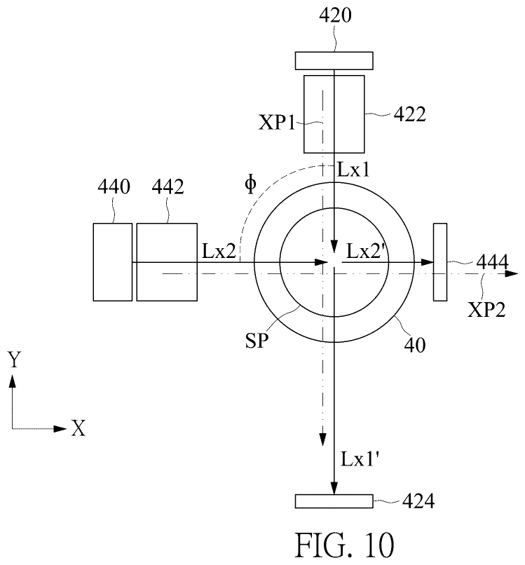

FIG. 8 is a functional block diagram of the composite semiconductor inspection system in the third embodiment of the present disclosure. FIG. 9 depicts the system architecture diagram, and FIG. 10 illustrates top view of the measurement architecture. This third embodiment provides another composite semiconductor inspection system 4, comprising a multi-axis sample stage 40, X-ray measurement subsystems 42 and 44, and a processing device 36. In this embodiment, components identical or similar to those in the first embodiment are denoted by similar reference numerals, and their descriptions are omitted to avoid redundancy.

The multi-axis sample stage 40 is similar to the multi-axis sample stage 10 in the first embodiment. The X-ray measurement subsystems 42 and 44 are fundamentally similar to the X-ray measurement subsystem 14. The X-ray measurement subsystem 42 includes an X-ray generator 420, an X-ray optical element group 422, and an X-ray detector 424. The X-ray measurement subsystem 44 includes an X-ray generator 440, an X-ray optical element group 442, and an X-ray detector 444. The X-ray generators 420 and 440 are used to generate measurement X-ray beams Lx1 and Lx2, respectively, which may have a wavelength range greater than 0.1 nanometers and may include hard X-rays, soft X-rays, or gamma rays.

When the measurement X-ray beams Lx1 and Lx2 irradiate the sample to-be-tested SP, different incidence angles may cause reflection, diffraction, scattering, or penetration to produce the X-ray signals to-be-measured Lx1′ and Lx2, respectively. By positioning the X-ray detectors 424 and 444 appropriately, they can be used to receive the X-ray signals to-be-measured Lx1′ and Lx2 resulting from reflection, diffraction, scattering, or penetration, and generate the X-ray spectrum information corresponding thereto.

It should be noted that the main difference between the third embodiment and the first embodiment lies in the replacement of the optical measurement subsystem 12 with the X-ray measurement subsystem 42 in the third embodiment. As shown in FIG. 10, the X-axis and Y-axis form a reference plane. The X-ray measurement subsystem 42 projects an X-ray measurement path XP1 onto this reference plane, while the X-ray measurement subsystem 44 projects an X-ray measurement path XP2 onto the same plane. These paths XP1 and XP2 are perpendicular to each other. Consequently, the composite semiconductor inspection system 4 provided by the present disclosure achieves anisotropic measurement capabilities. For instance, while the X-ray measurement subsystem 42 performs measurements, the X-ray measurement subsystem 44 can simultaneously measure at a specified azimuth angle ϕ, so as to achieve anisotropic measurements in real-time. This significantly enhances data throughput and reduces the time required to generate X-ray spectrum information. It is conceivable that consistent measurement conditions for both X-ray measurement subsystems 42 and 44 could also achieve isotropic measurement capabilities.

On the other hand, the X-ray generator 420 and the X-ray detector 424 may be mounted on the X-ray rotation mechanism 426, while the X-ray generator 440 and the X-ray detector 444 may be mounted on the X-ray rotation mechanism 446. The X-ray rotation mechanisms 426 and 446 may each include one or more robotic arms, with each robotic arm having the plurality of degrees of freedom. This configuration allows the X-ray generators 420 and 440, as well as the X-ray detectors 424 and 444, to rotate simultaneously or independently around the sample to-be-tested SP.

Additionally, although two sets of X-ray measurement subsystems 42 and 44 are employed in this embodiment, the present disclosure is not limited to this configuration. The number of optical measurement subsystems or X-ray measurement subsystems can be designed according to user requirements. Furthermore, the number of X-ray generators, X-ray optical element groups, and X-ray detectors is not restricted to the quantities illustrated in FIGS. 8 through 10. For example, only one set of X-ray generators and X-ray optical element groups may be provided, while the plurality of X-ray detectors are configured to simultaneously obtain X-ray signals resulting from reflection, diffraction, scattering, and fluorescence excitation.

Furthermore, similar to the first embodiment, the processing device 46 can execute a fitting analysis program based on the X-ray spectrum information generated by the X-ray measurement subsystems 42 and 44 to obtain the structural parameters of the sample to-be-tested SP as the analysis results. When the processing device 36 executes the fitting analysis program, it may include inputting the generated X-ray spectrum information into the neural network model 2 shown in FIG. 4. Since the details of data processing by the neural network model 2 are similar to those described in the first embodiment, they are omitted here for brevity.

### Beneficial Effects of the Embodiments

One beneficial effect of the present disclosure lies in the composite semiconductor inspection provided, which integrates X-ray measurement and optical measurement technologies. By employing neural network-based machine learning for result analysis, the information obtained from X-ray measurements can be fed back into the optical measurement model, enabling more accurate analysis results. In addition, this composite semiconductor inspection system combines the penetration capability of X-ray measurement technology with the speed of optical measurement technology, so as to provide a comprehensive and highly efficient measurement solution capable of analyzing various complex semiconductor components.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A composite semiconductor inspection system, comprising:
a multi-axis sample stage, configured to carry a sample to-be-tested;
an optical measurement subsystem, comprising:
a light source generator, configured to generate a measurement light beam with a wavelength within an optical wavelength range, the optical wavelength range at least covering an ultraviolet light band to a near-infrared light band;
an incident-end optical element group, configured to guide the measurement light beam to the sample to-be-tested;
a receiving-end optical element group, configured to receive an optical signal to-be-measured generated by the measurement light beam irradiating the sample to-be-tested; and
an optical receiver, configured to receive the to-be-measured optical signal guided by the receiving-end optical element group and generate optical spectrum information corresponding to the to-be-measured optical signal;
an X-ray measurement subsystem, comprising:
an X-ray generator, configured to generate a measurement X-ray beam with a wavelength greater than 0.1 nm;
an X-ray optical element group, configured to guide the measurement X-ray beam to the sample to-be-tested; and
an X-ray detector, configured to receive an X-ray signal to-be-measured generated when the measurement X-ray beam irradiates the sample to-be-tested and generate X-ray spectrum information corresponding to the X-ray signal to-be-measured; and
a processing device, configured to execute a fitting analysis program based on the optical spectrum information and the X-ray spectrum information to obtain one or more structural parameters of the sample to-be-tested as analysis results.

2. The composite semiconductor inspection system according to claim 1, wherein the multi-axis sample stage comprises a stage movement mechanism and a stage rotation mechanism, the stage movement mechanism is configured to move the sample to-be-tested along one or more of a first axis, a second axis, and a third axis, and the stage rotation mechanism is configured to rotate the sample to-be-tested about one or more of the first axis, the second axis, and the third axis.

3. The composite semiconductor inspection system according to claim 2, wherein the processing device is further configured to control the multi-axis sample stage to move and/or rotate such that the optical receiver receives a plurality of the to-be-measured optical signals generated at a plurality of optical measurement positions and/or a plurality of first optical measurement angles, and generates a plurality of pieces of optical spectrum information corresponding to the plurality of the to-be-measured optical signals, and such that the X-ray detector receives a plurality of the X-ray signals to-be-measured and generates a plurality of pieces of X-ray spectrum information corresponding to the plurality of the X-ray signals to-be-measured.

4. The composite semiconductor inspection system according to claim 3, wherein the light source generator and the optical receiver are disposed on an optical rotation mechanism such that the light source generator and the optical receiver simultaneously or separately rotate around the sample to-be-tested, and the X-ray generator and the X-ray detector are disposed on an X-ray rotation mechanism such that the X-ray generator and the X-ray detector simultaneously or separately rotate around the sample to-be-tested.

5. The composite semiconductor inspection system according to claim 4, wherein the processing device is further configured to control the optical rotation mechanism to rotate such that the light source generator directs the measurement light beam at a plurality of directions, and the optical receiver receives the plurality of the to-be-measured optical signals generated from a plurality of second optical measurement angles and generates the plurality of pieces of optical spectrum information corresponding to the plurality of the to-be-measured optical signals;
wherein the processing device is further configured to control the X-ray rotation mechanism to rotate such that the X-ray generator directs the measurement X-ray beam at the plurality of directions, and the X-ray detector receives the plurality of the X-ray signals to-be-measured generated from the plurality of X-ray measurement angles and generates the plurality of pieces of X-ray spectrum information corresponding to the plurality of the X-ray signals to-be-measured.

6. The composite semiconductor inspection system according to claim 5, wherein the processing device is further configured to control the optical rotation mechanism and/or the stage rotation mechanism to rotate such that the optical receiver receives the to-be-measured optical signal generated by reflection or scattering of the measurement light beam irradiating the sample to-be-tested;
wherein the processing device is further configured to control the X-ray rotation mechanism and/or the stage rotation mechanism to rotate such that the X-ray detector receives the X-ray signal to-be-measured generated by reflection, diffraction, scattering, or transmission of the measurement X-ray beam irradiating the sample to-be-tested.

7. The composite semiconductor inspection system according to claim 2, wherein the first axis and the second axis form a reference plane, the optical measurement subsystem forms an optical measurement path projected onto the reference plane, and the X-ray measurement subsystem forms an X-ray measurement path projected onto the reference plane, wherein the optical measurement path and the X-ray measurement path are perpendicular to each other.

8. The composite semiconductor inspection system according to claim 1, wherein the incident-end optical element group comprises one or more first optical elements, each of the first optical elements is a first optical filter, a first optical collimator, a first optical polarizer, or a first optical compensator, and the receiving-end optical element group comprises a plurality of second optical elements, each of the second optical elements is a second optical filter, a second optical collimator, a second optical polarizer, or a second optical compensator.

9. The composite semiconductor inspection system according to claim 1, wherein the X-ray optical element group comprises one or more X-ray optical elements, and each of the X-ray optical elements is an X-ray mirror group with a multilayer film structure, an X-ray slit, or an X-ray optical collimator.

10. The composite semiconductor inspection system according to claim 1, wherein the one or more structural parameters comprise one or more of thickness, roughness, density, critical dimension, line edge roughness, refractive index, and extinction coefficient.

11. The composite semiconductor inspection system according to claim 1, wherein the fitting analysis program comprises configuring the processing device to input the optical spectrum information and the X-ray spectrum information into a neural network model, and the neural network model comprises a pre-trained machine learning structure and a measurement data analysis structure, wherein the pre-trained machine learning structure is trained to generate a plurality of optical prediction results and a plurality of X-ray prediction results based on a target testing architecture and a plurality of preset structural parameters corresponding to the target testing architecture, and the measurement data analysis structure is trained to model and analyze the target testing architecture based on the optical prediction results, the X-ray prediction results, the optical spectrum information, and the X-ray spectrum information to produce the one or more structural parameters of the sample to-be-tested.

12. A composite semiconductor inspection system, comprising:
a multi-axis sample stage, configured to carry a sample to-be-tested;
at least two optical measurement subsystems, each comprising:
a light source generator, configured to generate a measurement light beam with a wavelength within an optical wavelength range, the optical wavelength range at least covering an ultraviolet light band to a near-infrared light band;
an incident-end optical element group, configured to guide the measurement light beam to the sample to-be-tested;
a receiving-end optical element group, configured to receive an optical signal to-be-measured generated by the measurement light beam irradiating the sample to-be-tested; and
an optical receiver, configured to receive the to-be-measured optical signal guided by the receiving-end optical element group and generate optical spectrum information corresponding to the to-be-measured optical signal; and
a processing device, configured to execute a fitting analysis program based on the optical spectrum information generated by the at least two optical measurement subsystems to obtain one or more structural parameters of the sample to-be-tested as analysis results.

13. The composite semiconductor inspection system according to claim 12, wherein the multi-axis sample stage comprises a stage movement mechanism and a stage rotation mechanism, the stage movement mechanism is configured to move the sample to-be-tested along one or more of a first axis, a second axis, and a third axis, and the stage rotation mechanism is configured to rotate the sample to-be-tested about one or more of the first axis, the second axis, and the third axis.

14. The composite semiconductor inspection system according to claim 13, wherein the processing device is further configured to control the multi-axis sample stage to move and/or rotate such that the optical receiver of each of the optical measurement subsystems receives a plurality of the to-be-measured optical signals generated at the plurality of optical measurement positions and/or the plurality of first optical measurement angles, and generates a plurality of pieces of optical spectrum information corresponding to the plurality of the to-be-measured optical signals.

15. The composite semiconductor inspection system according to claim 14, wherein the light source generator and the optical receiver of each of the optical measurement subsystems are disposed on an optical rotation mechanism such that the light source generator and the optical receiver simultaneously or separately rotate around the sample to-be-tested.

16. The composite semiconductor inspection system according to claim 15, wherein the processing device is further configured to control each of the optical rotation mechanisms to rotate such that the light source generator of each of the optical measurement subsystems directs the measurement light beam at a plurality of directions, and the optical receiver receives a plurality of the to-be-measured optical signals generated from a plurality of second optical measurement angles, and generates a plurality of pieces of optical spectrum information corresponding to the plurality of the to-be-measured optical signals.

17. The composite semiconductor inspection system according to claim 16, wherein the processing device is further configured to control the optical rotation mechanism and/or the stage rotation mechanism to rotate such that the optical receiver of each of the optical measurement subsystems receives the to-be-measured optical signal generated by reflection or scattering of the measurement light beam irradiating the sample to-be-tested.

18. The composite semiconductor inspection system according to claim 13, wherein the first axis and the second axis form a reference plane, wherein one of the optical measurement subsystems forms a first optical measurement path projected onto the reference plane, another one of the optical measurement subsystems forms a second optical measurement path projected onto the reference plane, and the first optical measurement path and the second optical measurement path are perpendicular to each other.

19. The composite semiconductor inspection system according to claim 1, wherein the fitting analysis program comprises configuring the processing device to input the optical spectrum information into a neural network model, and the neural network model comprises a pre-trained machine learning structure and a measurement data analysis structure, wherein the pre-trained machine learning structure is trained to generate a plurality of optical prediction results based on a target testing architecture and a plurality of preset structural parameters corresponding to the target testing architecture, and the measurement data analysis structure is trained to model and analyze the target testing architecture based on the optical prediction results and the optical spectrum information to produce the one or more structural parameters of the sample to-be-tested.

20. A composite semiconductor inspection system, comprising:
a multi-axis sample stage, configured to carry a sample to-be-tested;
at least two X-ray measurement subsystems, each comprising:
an X-ray generator, configured to generate a measurement X-ray beam with a wavelength greater than 0.1 nanometers;
an X-ray optical element group, configured to guide the measurement X-ray beam to the sample to-be-tested; and
an X-ray detector, configured to receive an X-ray signal to-be-measured generated when the measurement X-ray beam irradiates the sample and generate X-ray spectrum information corresponding to the X-ray signal to-be-measured; and
a processing device, configured to execute a fitting analysis program based on the X-ray spectrum information generated by the at least two X-ray measurement subsystems to obtain one or more structural parameters of the sample to-be-tested as analysis results.

21. The composite semiconductor inspection system according to claim 20, wherein the multi-axis sample stage comprises a stage movement mechanism and a stage rotation mechanism, the stage movement mechanism is configured to move the sample to-be-tested along one or more of a first axis, a second axis, and a third axis, and the stage rotation mechanism is configured to rotate the sample to-be-tested about one or more of the first axis, the second axis, and the third axis.

22. The composite semiconductor inspection system according to claim 21, wherein the processing device is further configured to control the multi-axis sample stage to move and/or rotate such that the X-ray detector of each X-ray measurement subsystem receives a plurality of the X-ray signals to-be-measured and generates a plurality of pieces of X-ray spectrum information corresponding to the plurality of the X-ray signals to-be-measured.

23. The composite semiconductor inspection system according to claim 22, wherein the X-ray generator and the X-ray detector of each X-ray measurement subsystem are disposed on an X-ray rotation mechanism such that the X-ray generator and the X-ray detector simultaneously or separately rotate around the sample to-be-tested.

24. The composite semiconductor inspection system according to claim 23, wherein the processing device is further configured to control the X-ray rotation mechanism to rotate such that the X-ray generator of each X-ray measurement subsystem directs the measurement X-ray beam at a plurality of directions, and the X-ray detector of each X-ray measurement subsystem receives the plurality of the X-ray signals to-be-measured generated from the plurality of second X-ray measurement angles, and generates the plurality of pieces of X-ray spectrum information corresponding to the plurality of the X-ray signals to-be-measured; wherein the processing device is further configured to control the X-ray rotation mechanism to rotate such that the X-ray generator directs the measurement X-ray beam at the plurality of directions, and the X-ray detector receives the plurality of the X-ray signals to-be-measured generated from the plurality of X-ray measurement angles, and generates the plurality of pieces of X-ray spectrum information corresponding to the plurality of the X-ray signals to-be-measured.

25. The composite semiconductor inspection system according to claim 24, wherein the processing device is further configured to control the X-ray rotation mechanism and/or the stage rotation mechanism to rotate such that the X-ray detector receives the X-ray signal to-be-measured generated by reflection or scattering of the measurement X-ray beam irradiating the sample to-be-tested;
wherein the processing device is further configured to control the X-ray rotation mechanism and/or the stage rotation mechanism to rotate such that the X-ray detector receives the X-ray signal to-be-measured generated by reflection, diffraction, scattering, or transmission of the measurement X-ray beam irradiating the sample to-be-tested.

26. The composite semiconductor inspection system according to claim 21, wherein the first axis and the second axis form a reference plane, wherein one of the X-ray measurement subsystems forms a first X-ray measurement path projected onto the reference plane, another one of the X-ray measurement subsystems forms a second X-ray measurement path projected onto the reference plane, and the first X-ray measurement path and the second X-ray measurement path are perpendicular to each other.

27. The composite semiconductor inspection system according to claim 20, wherein the X-ray optical element group of each X-ray measurement subsystem comprises one or more X-ray optical elements, and each X-ray optical element is an X-ray mirror group with a multilayer film structure, an X-ray slit, or an X-ray collimator.

28. The composite semiconductor inspection system according to claim 20, wherein the fitting analysis program comprises configuring the processing device to input the X-ray spectrum information into a neural network model, and the neural network model comprises a pre-trained machine learning structure and a measurement data analysis structure, wherein the pre-trained machine learning structure is trained to generate a plurality of X-ray prediction results based on a target testing architecture and a plurality of preset structural parameters corresponding to the target testing architecture, and the measurement data analysis structure is trained to model and analyze the target testing architecture based on the X-ray prediction results and the X-ray spectrum information to produce the one or more structural parameters of the sample to-be-tested.
